(19) United States
(12) Patent Application Publication
(10) Pub. No.: US 2011/0148992 A1
(43) Pub. Date: Jun. 23, 2011

(54) PIEZOELECTRIC ELEMENT, LIQUID JET HEAD AND PRINTER

(75) Inventors: Hiromu MIYAZAWA, Azumino (JP); Taku AOYAMA, Setagaya (JP); Jiro KATO, Suwa (JP); Koji OHASHI, Chino (JP)

(73) Assignee: SEIKO EPSON CORPORATION, Tokyo (JP)

(21) Appl. No.: 13/034,996

(22) Filed: Feb. 25, 2011

Related U.S. Application Data
(63) Continuation of application No. 12/048,268, filed on Mar. 14, 2008.

(30) Foreign Application Priority Data
Mar. 15, 2007 (JP) 2007-066613
Jan. 11, 2008 (JP) 2008-004519

(51) Int. Cl. B41J 2/045; H01L 41/04

(52) U.S. Cl. 347/68; 310/357

(57) ABSTRACT

A piezoelectric element includes: a base substrate; a lower electrode formed above the base substrate; a piezoelectric layer that is formed above the lower electrode, and formed from a perovskite type oxide; and an upper electrode formed above the piezoelectric layer, wherein the piezoelectric layer is oriented to (100) crystal orientation in the pseudo-cubic crystal expression, and a crystal of the perovskite type oxide in a direction parallel to a lower surface of the piezoelectric layer has a lattice constant greater than a lattice constant of the crystal of the perovskite type oxide in a direction orthogonal to the lower surface of the piezoelectric layer.

### CROSS-REFERENCE TO RELATED APPLICATIONS

This application is a continuation of U.S. patent application Ser. No. 12/048,268 filed on Mar. 14, 2008. This application claims the benefit of Japanese Patent Application Nos: 2007-066613, filed Mar. 15, 2007 and 2008-004519, filed Jan. 11, 2008. The disclosures of the above applications are incorporated herein by reference.

### BACKGROUND

1. Technical Field

The present invention relates to piezoelectric elements, liquid jet heads and printers.

2. Related Art

The ink jet method has now been put into practical use as a high resolution and high speed printing method. For ejecting ink droplets, it is useful to employ piezoelectric elements with the structure in which a piezoelectric layer is sandwiched by electrodes. As a representative material for the piezoelectric layer, lead zirconate titanate (Pb (Zr, Ti) O₃:PZT) that is a perovskite type oxide may be enumerated (see, for example, Japanese Laid-open patent application JP-A-2001-223404).

### SUMMARY

In accordance with an advantage of some aspects of the invention, piezoelectric elements having favorable characteristics can be provided. In accordance with another advantage of the aspects of the invention, liquid jet heads and printers having the piezoelectric elements are provided.

A piezoelectric element in accordance with an embodiment of the invention includes: a base substrate; a lower electrode formed above the base substrate; a piezoelectric layer that is formed above the lower electrode, and formed from a perovskite type oxide; and an upper electrode formed above the piezoelectric layer, wherein the piezoelectric layer is oriented to (100) crystal orientation in the pseudo-cubic crystal expression, and crystal of the perovskite type oxide in a direction parallel to a lower surface of the piezoelectric layer has a lattice constant greater than a lattice constant of crystal of the perovskite type oxide in a direction orthogonal to the lower surface of the piezoelectric layer.

According to the piezoelectric element in accordance with the present embodiment, the lattice constant of a crystal of the perovskite type oxide in a direction parallel to a lower surface of the piezoelectric layer is greater than the lattice constant of the crystal of the perovskite type oxide in a direction orthogonal to the lower surface of the piezoelectric layer. As a result, the piezoelectric element can have favorable characteristics. This shall be confirmed by experimental examples to be described below.

It is noted that, in the descriptions concerning the invention, the term “above” may be used, for example, as “a specific element (hereafter referred to as “A”) is formed ‘above’ another specific element (hereafter referred to as “B”).” In the descriptions concerning the invention, in this case, the term “above” is assumed to include a case in which A is formed directly on B, and a case in which A is formed above B through another element.

In the invention, the “psuedo-cubic” is a state of a crystal structure that is assumed to be cubic.

In the present invention, the statement “oriented to (100) crystal orientation” includes the case where the entire crystal is oriented to (100) crystal orientation, and the case where most of the crystals (for example, 90% or more) are oriented to (100) crystal orientation, and the remaining crystals that are not oriented to (100) may be oriented to another crystal orientation, for example, in (111) or the like. In other words, being “oriented to (100) crystal orientation” may be interchangeable with “being preferentially oriented to (100) crystal orientation.”

In the piezoelectric element in accordance with an aspect of the invention, the lattice constant of the crystal of the perovskite type oxide in a first direction among the directions parallel to the lower surface of the piezoelectric layer may be the same as the lattice constant of the crystal of the perovskite type oxide in a second direction, among the directions parallel to the lower surface of the piezoelectric layer, orthogonal to the first direction in the pseudo-cubic crystal expression.

In the piezoelectric element in accordance with an aspect of the embodiment of the invention, the crystal structure of the piezoelectric layer may be a monoclinic structure.

In the present invention, the statement “the crystal structure is a monoclinic structure” includes the case where the entire crystals are in a monoclinic structure, and the case where most of the crystals (for example, 90% or more) are in a monoclinic structure, and the remaining crystals that are not in a monoclinic structure have a tetragonal crystal structure.

In the piezoelectric element in accordance with an aspect of the embodiment of the invention, the perovskite type oxide may be expressed by a general formula ABO₃, where A includes lead (Pb), and B includes zirconium (Zr) and titanium (Ti).

In the piezoelectric element in accordance with an aspect of the embodiment of the invention, the element B may further include lead (Pb).

In the piezoelectric element in accordance with an aspect of the embodiment of the invention, the element B may be expressed by (Pb_{X} Zr_{Y} Ti_{Z}), where X may be 0.025 or more but 0.1 or less, and the sum of Y and Z may be 1.

In the piezoelectric element in accordance with an aspect of the embodiment of the invention, when the amount of lead in the piezoelectric layer is t, and the amount of transition metal is u, t/u may be 1.05 or more but 1.20 or less.

In the piezoelectric element in accordance with an aspect of the embodiment of the invention, the perovskite type oxide may be lead zirconate titanate.

A liquid jet head in accordance with an embodiment of the invention includes any one of the piezoelectric elements described above.

A liquid jet head in accordance with an embodiment of the invention includes a nozzle plate having a nozzle aperture connecting to a pressure chamber, and the above-described piezoelectric element formed above the nozzle plate, wherein the pressure chamber may be formed by an opening section in a substrate of the base substrate.

A printer in accordance with an embodiment of the invention includes any one of the piezoelectric elements described above.

A printer in accordance with an embodiment of the invention may include a head unit having the above-described liquid jet head, a head unit driving section that reciprocally moves the head unit, and a controller section that controls the head unit and the head unit driving section.

### BRIEF DESCRIPTION OF THE DRAWINGS

FIG. 1 is a schematic cross-sectional view of a piezoelectric element in accordance with an embodiment of the invention.

FIG. 2 is a graph schematically showing a crystal of perovskite type oxide composing a piezoelectric layer.

FIG. 3 is a schematic cross-sectional view showing a step of a method for manufacturing a piezoelectric element in accordance with an embodiment of the invention.

FIG. 4 is an exploded perspective view schematically showing a liquid jet head in accordance with an embodiment of the invention.

FIG. 5 is a 2θ-ψ map obtained by X-ray diffraction measurement conducted on an experimental sample in accordance with the embodiment.

FIG. 6 is a graph showing the result of Raman scattering measurement conducted on experimental samples in accordance with the embodiment.

FIG. 7 is a graph showing the result of Raman scattering measurement conducted on experimental samples in accordance with the embodiment.

FIG. 8 is a perspective view schematically showing a printer in accordance with an embodiment of the invention.

### DESCRIPTION OF EXEMPLARY EMBODIMENTS

Preferred embodiments of the invention are described below with reference to the accompanying drawings.

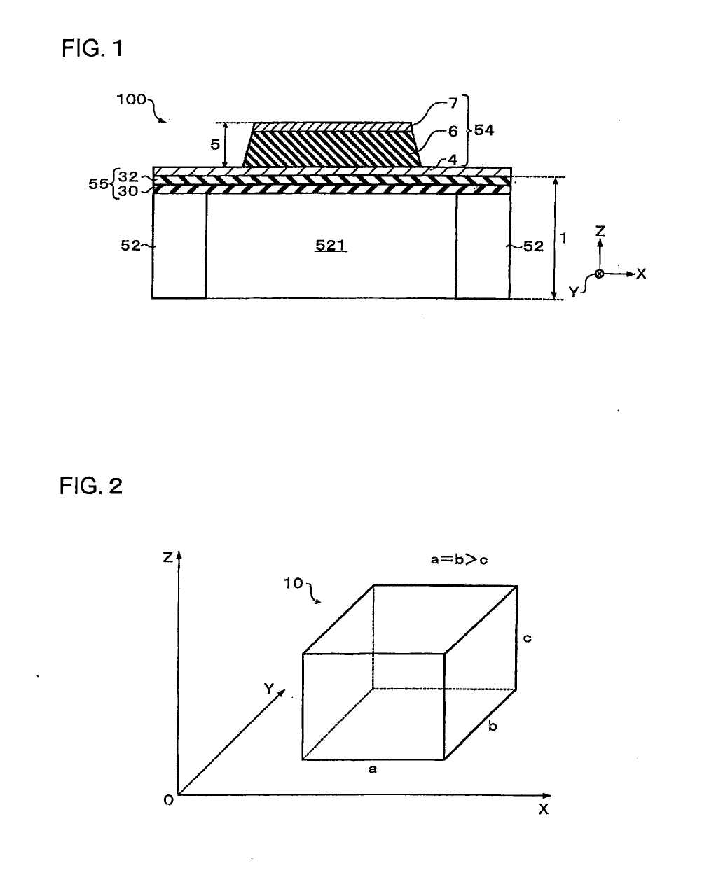

1. First, a piezoelectric element 100 in accordance with an embodiment of the invention is described. FIG. 1 is a schematic cross-sectional view of the piezoelectric element 100.

As shown in FIG. 1, the piezoelectric element 100 includes a base substrate 1 and a driving section 54. The base substrate 1 may have a substrate 52 and an elastic plate 55.

As the substrate 52, for example, a (110) single crystal silicon substrate (with a plane orientation <110>) may be used. The substrate 52 has an opening section 521. The opening section 521 may form, for example, a pressure chamber of an ink jet recording head. The shape of the opening section 521 is, for example, a cuboid that is 65 μm wide, 1 mm long, and 80 μm high.

The elastic plate 55 is formed on the substrate 52. The elastic plate 55 may include, for example, an etching stopper layer 30, and an elastic layer 32 formed on the etching stopper layer 30. The etching stopper layer 30 may be formed from, for example, silicon oxide (SiO₂). The thickness of the etching stopper layer 30 is, for example, 1 μm. The elastic layer 32 may be formed from, for example, zirconium oxide (ZrO₂). The thickness of the elastic layer 32 is, for example, 1 μm. It is noted that the flexible plate 55 may be provided without the etching stopper layer 30 (though its illustration is not shown).

The driving section 54 is formed on the elastic plate 55. The driving section 54 is capable of flexing the elastic plate 55. The driving section 54 may include a lower electrode 4 formed on the elastic plate 55 (more specifically, on the elastic layer 32), a piezoelectric layer 6 formed on the lower electrode 4, and an upper electrode 7 formed on the piezoelectric layer 6. The major portion of the driving section 54 is formed above, for example, the opening section 521, and a portion of the driving section 54 (more specifically, the lower electrode 4) may also be formed on the substrate 52, for example.

The lower electrode 4 is one of electrodes for applying a voltage to the piezoelectric layer 6. As the lower electrode 4, for example, a laminated film in which a layer of polycrystalline iridium (Ir) (with 10 nm thick) is laminated on a layer of polycrystal platinum (Pt) (with 150 nm thick) may be used. It is noted that the Ir layer may become a layer of iridium oxide through the step of sintering a precursor layer for the piezoelectric layer 6 to be described below.

The piezoelectric layer 6 is composed of a piezoelectric material of perovskite type oxide. FIG. 2 schematically shows the crystal 10 of the perovskite type oxide that composes the piezoelectric layer 6. As shown in FIG. 2, the lattice constants a and b of the crystal 10 of the perovskite type oxide in directions parallel to the lower surface of the piezoelectric layer 6 (in X direction and Y direction shown in FIG. 1 and FIG. 2) are greater than the lattice constant c of the crystal 10 of the perovskite type oxide in a direction orthogonal to the lower surface of the piezoelectric layer 6 (Z direction shown in FIG. 1 and FIG. 2). Also, the lattice constant a of the crystal 10 of the perovskite type oxide in a first direction (X direction) among the directions parallel to the lower surface of the piezoelectric layer 6 is the same as the lattice constant b of the crystal 10 of the perovskite type oxide in a second direction (Y direction) among the directions parallel to the lower surface of the piezoelectric layer 6, orthogonal to the first direction in the psuedo cubic expression. The above-described relations may be expressed by the following formula.

a=b>c Formula (1)

As the perovskite type oxide, it is possible to use a perovskite type oxide that is expressed by, for example, a general formula ABO₃, where A (A site) includes lead (Pb), and B (B site) includes zirconium (Zr) and titanium (Ti).

Also, B (B site) may preferably include a predetermined amount of lead (Pb), because of the following reason.

First, let us consider the case where Pb exists in a thin film in an amount that is 10% in excess with respect to B site transition metals (Zr and Ti). Diffraction peaks due to heterogeneous phases do not appear in X-ray diffraction analysis on the samples with excessive Pb. It is assumed from this analysis result that the 10% excessive Pb does not precipitate in the thin film as heterogeneous phases, but is integrated in the perovskite structure. Accordingly, when the amount of excessive Pb in the thin film with respect to the stoichiometric composition is δ, the aforementioned general formula “ABO₃” can be expressed as “Pb_{1+δ}BO₃” when A is composed of Pb. In this expression, B indicates transition metals.

Then, considering the location where the excessive Pb exists, it can be concluded that the excessive Pb uniformly exists in the A site and the B site. This is because, in the perovskite structure, Pb ions, that are cations, can stably exist in terms of electrostatic potential, when they exit at the positions of A site ions and B site ions which are the same cations. Accordingly, the excessive amount δ of Pb with respect to the B site transition metals is allocated in an amount of δ/2 to each of the A site and the B site. In other words, the aforementioned general formula “ABO₃” can be expressed as “Pb_{1+(δ/2)} (B, Pb_{δ/2}) O₃). By representing the crystal with this expression, the charge balance can be maintained, and the crystal becomes stable. It is noted that, even in this expression, B indicates transition metals.

Next, the existence of the excessive Pb at the B site of the perovskite structure is experimentally proved by Raman scattering measurement. Table 1 shows the relation between the amount of Pb in the piezoelectric layer 6 and the shift amount of wavenumber (cm⁻¹) of A1 (3LO) peak corresponding to optical phonons at the B site. The amount of Pb is expressed in ratio with respect to the amount of transition metals (the sum of Zr amount and Ti amount). The reference center wavenumber is 712 cm⁻¹. According to Table 1, as the amount of Pb in the piezoelectric layer 6 increases, the vibration peak of the B site shifts to lower wavenumbers. On the other hand, even when the amount of Pb is increased, no change is observed in the position of A1 (2TO) peak (near 325 cm⁻¹) that has small contribution to the optical phonons at the B site. This accordingly indicates that, when the amount of Pb is increased, Pb atoms replaces the B site. In other words, it directly indicates that excessive Pb is taken in the B site.

TABLE 1

| | Shift Amount of |
|---|---|
| Amount of Pb | Wavenumber (cm⁻¹) |
| 1.03 | 0.0 |
| 1.06 | −0.7 |
| 1.09 | −1.7 |
| 1.12 | −2.4 |
| 1.15 | −3.7 |

Table 2 shows the relation between δ and the amount of piezoelectric displacement η (nm), when the amount of Pb with respect to the amount of transition metals (Zr and Ti) contained in the piezoelectric layer 6 is 1+δ, in other words, the aforementioned formula is expressed as “Pb_{1+(δ/2)} (Zr, Ti, Pb_{δ/2}) O₃”. In this case, the composition ratio of Zr and Ti was 1:1 (Zr:Ti=1:1). The thickness of the piezoelectric layer 6 was 1.2 μm. The piezoelectric layer 6 was interposed between the lower electrode 4 and the upper electrode 7 which were composed of Pt—Ir alloy. The thickness of each of the lower electrode 4 and the upper electrode 7 was 200 nm. The substrate 52 was a (110) silicon substrate. Also, the amount of piezoelectric displacement η (nm) was measured by a laser interferometer, and 1×1 mm square samples were used for the measurement. Also, the piezoelectric layer 6 alone was dissolved by acid, and the ICP analysis was conducted to measure the composition of Pb and transition metals in the thin film. By so doing, the amount of Pb in the piezoelectric layer 6 can be measured while eliminating influence of Pb diffused in the lower electrode 4.

TABLE 2

| | Amount of |
|---|---|
| | Piezoelectric |
| δ | Displacement η (nm) |
| −0.05 | 0.7 |
| 0 | 1.3 |
| +0.05 | 2.4 |
| +0.1 | 3.6 |
| +0.15 | 3.0 |
| +0.2 | 2.1 |
| +0.25 | 1.2 |

It is observed from Table 2 that, when a predetermined amount of Pb is present at the B site, the amount of piezoelectric displacement η becomes larger. When the value of δ is 0.1, the amount of piezoelectric displacement η reaches the maximum value. Also, in order to obtain a large amount of piezoelectric displacement η, the value of δ may preferably be 0.05 or more but 0.2 or less, and more preferably, 0.1 or more but 0.15 or less. In other words, when the B site is expressed as (Pb_{X} Zr_{Y} Ti_{Z}), and X is δ/2 (X=δ/2), the value of X may preferably be 0.025 or more but 0.1 or less, and more preferably, 0.05 or more but 0.075 or less. It is noted that the sum of Y and Z is 1. Also, considering the aforementioned preferred range of δ, the relation (t/u) between the amount t of Pb in the piezoelectric layer 6 and the amount u of transition metals may preferably be 1.05 or more but 1.20 or less, and more preferably, 1.10 or more but 1.15 or less.

As the perovskite type oxide, for example, lead zirconate titanate (Pb (Zr, Ti) O₃:PZT), and lead zirconate titanate solid solution may be enumerated. As the lead zirconate titanate solid solution, for example, lead zirconate titanate niobate (Pb (Zr, Ti, Nb) O₃:PZTN) may be used.

For example, when the piezoelectric layer 6 is composed of lead zirconate titanate (Pb (Zrₓ Ti₁₋ₓ) O₃), the Zr composition x may be, for example, 0.5. The thickness of the piezoelectric layer 6 may be, for example, 1.0 μm.

The piezoelectric layer 6 is oriented to (100) crystal orientation in the pseudo-cubic crystal expression. The crystal structure of the piezoelectric layer 6 may preferably be a monoclinic structure. Also, the polarization direction of the piezoelectric layer 6 may preferably be tilted with respect to a direction orthogonal to the film surface (the thickness direction of the piezoelectric layer 6), which is in an engineered domain arrangement.

The upper electrode 7 is the other electrode for applying a voltage to the piezoelectric layer 6. As the upper electrode 7, for example, a layer of iridium (Ir) (with 200 nm thick) may be used.

The piezoelectric layer 6 and the upper electrode 7 may form, for example, a columnar laminate (columnar section) 5. The width of the columnar section 5 (the width of the lower surface of the piezoelectric layer 6) is, for example, 50 μm, and the length of the columnar section 5 (the length of the lower surface of the piezoelectric layer 6) is, for example, 1 mm.

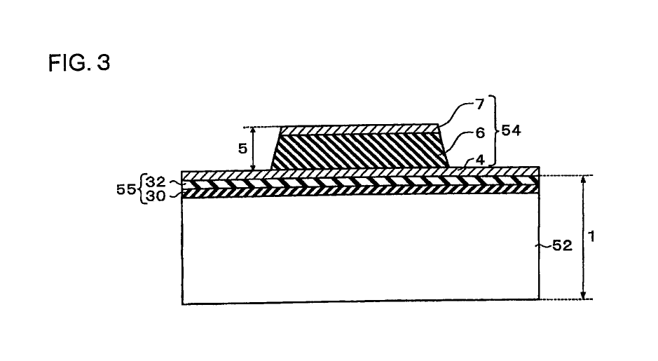

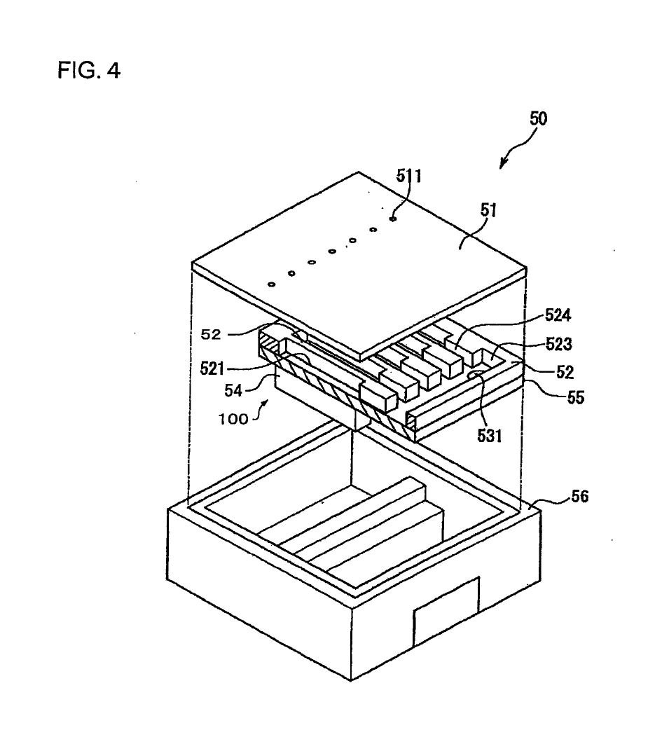

2. Next, a method for manufacturing a piezoelectric element 100 in accordance with an embodiment of the invention is described. FIG. 3 is a schematic cross-sectional view showing a step of the method for manufacturing the piezoelectric element 100 in accordance with the embodiment, which corresponds to the cross-sectional view shown in FIG. 1.

(1) First, as shown in FIG. 3, the elastic plate 55 is formed on the substrate 52. More specifically, for example, the etching stopper layer 30 and the elastic layer 32 are successively formed in this order over the entire surface of the substrate 52. By this step, the elastic plate 55 having the etching stopper layer 30 and the elastic layer 32 is formed. The etching stopper layer 30 may be formed by, for example, a thermal oxidation method. The elastic layer 32 may be formed by, for example, a sputter method.

(2) Next, as shown in FIG. 3, the driving section 54 is formed on the elastic plate 55. More specifically, first, a lower electrode layer 4, a piezoelectric layer 6 and an upper electrode layer 7 are successively formed in this order over the entire surface of the elastic plate 55.

The lower electrode layer 4 may be formed by, for example, sputtering.

The piezoelectric layer 6 may be formed by, for example, a sol-gel method (solution method). An example of forming the piezoelectric layer 6 composed of PZT is described below.

First, a solution (of piezoelectric materials) in which organometallic compounds respectively containing Pb, Zr and Ti are dissolved in a solvent is coated on the entire surface of the lower electrode 4 by a spin coat method. For example, by changing the mixing ratio of the organometallic compounds respectively containing Zr and Ti in the solution, the composition ratio of Zr and Ti (Zr:Ti) can be adjusted. For example, the organometallic compounds may be mixed such that the Zr composition=Zr/(Zr+Ti) equals to 0.5. It is noted that the composition of Pb can also be adjusted by changing the mixing ratio of the organometallic compounds.

Next, by conducting a heat treatment (for drying step and degreasing step), a precursor layer for the piezoelectric layer 6 can be formed. The temperature of the drying step may preferably be, for example, 150° C. or higher but 200° C. or lower. Also, the time for the drying step may preferably be, for example, 5 minutes or longer. In the degreasing step, organic components remaining in the PZT precursor layer after the drying step may be thermally decomposed into NO₂, CO₂, H₂O and the like and thus removed. The temperature of the degreasing step may be, for example, about 300° C.

It is noted that, in forming the precursor layer, the precursor layer may be formed in a plurality of divided rounds, not all at once. More specifically, for example, a series of the steps of coating of the piezoelectric material, drying and degreasing may be repeated multiple times.

Next, the precursor layer is sintered. In this sintering step, the PZT precursor layer is heated and thereby being crystallized. The temperature for the sintering step may be, for example, 700° C. The time duration for the sintering step may preferably be 5 minutes or longer but 30 minutes or shorter. The apparatus that may be used for the sintering step includes, without any particular limitation, a diffusion furnace, a RTA (rapid thermal annealing) apparatus, or the like. It is noted that the sintering step may be conducted, for example, at each one cycle of coating the piezoelectric material, drying and degreasing.

By the steps described above, the piezoelectric layer 6 is formed.

The upper electrode layer 7 is formed by, for example, sputtering.

Next, for example, the upper electrode layer 7 and the piezoelectric layer 6 are patterned, thereby forming the columnar section 5 in a desired shape. Then, for example, the lower electrode layer 4 may be patterned. Each of the layers may be patterned by using, for example, lithography technique and etching technique. The lower electrode layer 4, the piezoelectric layer 6 and the upper electrode layer 7 may be patterned independently as each of the layers is formed, or together as each set of plural layers is formed.

By the steps described above, the driving section 54 having the lower electrode 4, the piezoelectric layer 6 and the upper electrode 7 is formed.

(3) Next, as shown in FIG. 1, the substrate 52 is patterned, thereby forming the opening section 521. The substrate 52 may be patterned by using, for example, lithography technique and etching technique. The opening section 521 may be formed by, for example, etching a portion of the substrate 52 in a manner to expose the etching stopper layer 30. In this etching step, the etching stopper layer 30 may be functioned as a stopper to the etching. In other words, when etching the substrate 52, the etching rate of the etching stopper layer 30 is lower than the etching rate of the substrate 52.

By the steps described above, as shown in FIG. 1, the piezoelectric element 100 in accordance with the present embodiment is fabricated.

3. According to the piezoelectric layer 100 in accordance with the present embodiment, the lattice constants a and b of the crystal 10 of the perovskite type oxide in directions parallel to the lower surface of the piezoelectric layer 6 are greater than the lattice constant c of the crystal 10 of the perovskite type oxide in a direction orthogonal to the lower surface of the piezoelectric layer 6. As a result, the piezoelectric element 100 has favorable characteristics. This has been confirmed by experimental examples to be described below.

4. Next, a liquid jet head having the above-described piezoelectric element is described. Here, an example in which the liquid jet head 50 in accordance with the present embodiment is an ink jet type recording head is described.

FIG. 4 is a schematic exploded perspective view of the liquid jet head 50 in accordance with the embodiment of the invention, and shows the head upside down with respect to a state in which it is normally used. It is noted that the illustration of the driving section 54 of the piezoelectric element 100 is simplified in FIG. 4 for the sake of convenience.

The liquid jet head 50 includes the piezoelectric element 100 shown, for example, in FIG. 1, and the nozzle plate 51. The liquid jet head 50 may further include a housing 56.

The nozzle plate 51 has nozzle apertures 511 connecting to a pressure chamber 521. Ink is ejected through the nozzle apertures 511. The nozzle plate 51 may be provided with, for example, a row of multiple nozzle apertures 511. The nozzle plate 51 is formed from, for example, a rolled plate of stainless steel (SUS). The nozzle plate 51 is affixed to a lower side (an upper side in the illustration of FIG. 4) of the substrate 52 in the sate in which it is normally used. The housing 56 can store the nozzle plate 51 and the piezoelectric elements 100. The housing 56 may be formed with, for example, any one of various resin materials or any one of various metal materials.

The substrate 52 of the piezoelectric element 100 divides the space between the nozzle plate 51 and the elastic plate 55, thereby defining a reservoir (liquid reserving section) 523, supply ports 524 and a plurality of cavities (pressure chambers) 521. The elastic plate 55 of the piezoelectric element 100 is provided with a through-hole 531 that penetrates the elastic plate 55 in its thickness direction. The reservoir 523 temporarily stores ink that is supplied from outside (for example, from an ink cartridge) through the through-hole 531. Ink is supplied to each of the cavities 521 from the reservoir 523 through each of the corresponding supply ports 524.

Each of the cavities 521 is formed from an opening section 521 of the substrate 52. Each one of the cavities 521 is provided for each one of the nozzles 511. The cavity 521 is capable of changing its volume by deformation of the elastic plate 55. The volume change causes ink to be ejected from the cavity 521.

The driving section 54 is electrically connected to a piezoelectric element driving circuit (not shown), and is capable of operating (vibrating, deforming) based on signals provided by the piezoelectric element driving circuit. The elastic plate 55 deforms by deformation of the driving section 54, and can instantaneously increase the inner pressure of the cavity 521.

The aforementioned example is described with reference to the case where the liquid jet head 50 is an ink jet type recording head. However, the liquid jet head in accordance with the invention is also applicable as, for example, a color material jet head used for manufacturing color filters for liquid crystal displays and the like, an electrode material jet head used for forming electrodes for organic EL displays, FED (Field Emission Displays) and the like, and a bioorganic material jet head used for manufacturing bio-chips.

5. Next, experimental examples are described.

According to the present experimental example, a liquid jet head 50 having the piezoelectric element 100 in accordance with the present embodiment was manufactured. As the piezoelectric layer 20 of the piezoelectric element 100 in accordance with the present embodiment, lead zirconate titanate Pb (Zr_{0.5}Ti_{0.5})O₃ was used.

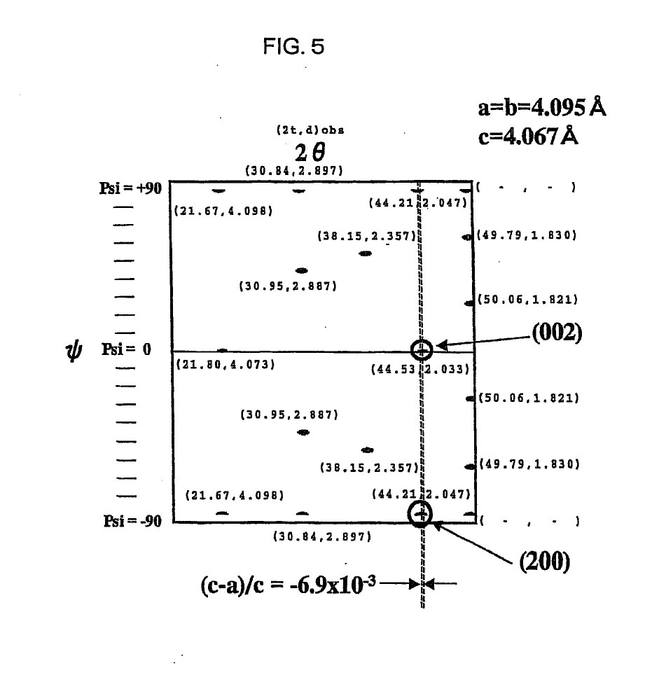

FIG. 5 is a 2θ-ψ map obtained by X-ray diffraction measurement conducted on the experimental sample in accordance with the embodiment. As shown in FIG. 5, the peak of the (200) plane of the piezoelectric layer 6 in the pseudo-cubic crystal expression was observed at 2θ=44.21°. Also, the peak of the (002) plane of the piezoelectric layer 6 in the pseudo-cubic crystal expression was observed at 2θ=44.53°. It is understood from the measurement results that the lattice constants a and b of the crystal 10 of the perovskite type oxide in directions parallel to the lower surface of the piezoelectric layer 6 were 4.095 Å, and the lattice constant c of the crystal 10 of the perovskite type oxide in a direction orthogonal to the lower surface of the piezoelectric layer 6 was 4.067 Å. Therefore the aforementioned formula (1), a=b>c, was confirmed.

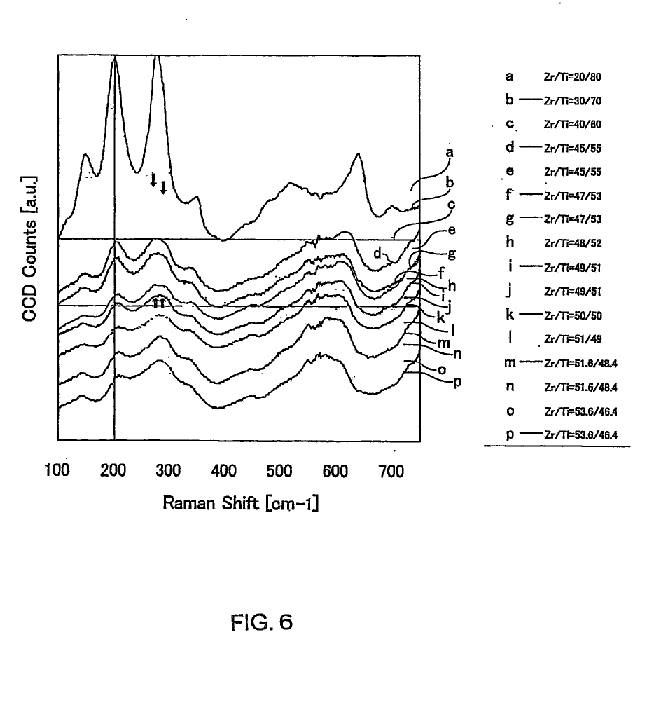

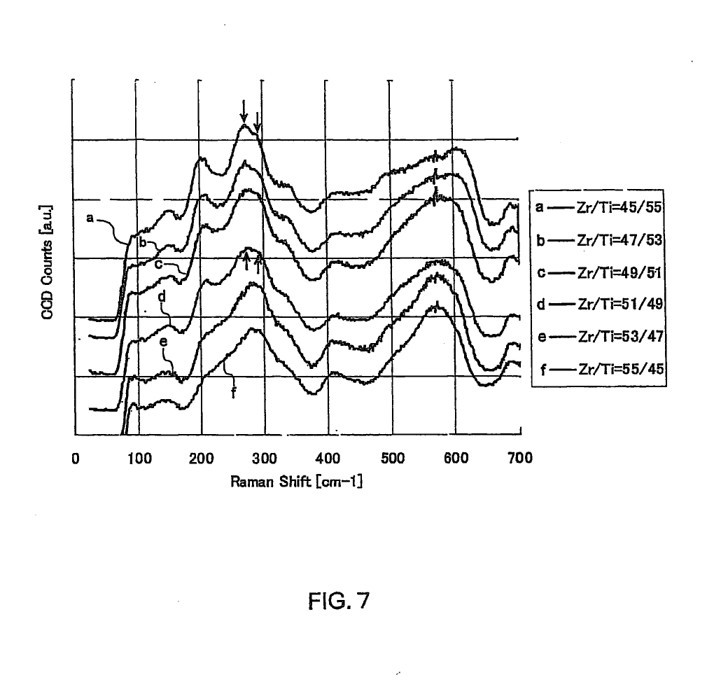

FIG. 6 and FIG. 7 are graphs showing the results of Raman scattering measurement conducted on the experimental samples in accordance with the embodiment. As the measurement conditions, the wavelength of the excitation laser was 514.5 nm, the measurement temperature was 4.2 K, the measurement system used was a backscattering arrangement type, the object lens with 50-time magnification power was used, and the measurement time was 20 minutes. Natural oscillations appearing at wavenumbers (Raman shift) in a 250-300 [cm⁻¹] region have degeneration and division caused by deterioration of the symmetricity of the crystal. This phenomenon can be used to evaluate the symmetricity of the crystal. More specifically, when the lead zirconate titanate has a structure with high crystal symmetricity, such as, a tetragonal structure or a rhombohedral structure among the perovskite type structures, the peaks are degenerated to one. On the other hand, when the lead zirconate titanate has a structure with low crystal symmetricity, such as, a monoclinic structure, the peak is divided into two. Therefore the evaluation is carried out through checking whether there is one peak or two peaks.

FIG. 6 shows the results of Raman scattering measurement conducted on the experimental samples where an Ir layer was used as the lower electrode 4. As shown in FIG. 6, the aforementioned division of the natural oscillation peak was observed when the composition ratio of Zr and Ti (Zr/Ti) was 40/60 (c in the figure) or more but 50/50 (k in the figure) or less.

FIG. 7 shows the results of Raman scattering measurement conducted on the experimental samples where a LaNiO₃ layer was used as the lower electrode 4. As shown in FIG. 7, the aforementioned division of the natural oscillation peak was observed when the composition ratio of Zr and Ti (Zr/Ti) was 45/55 (a in the figure) or more but 51/49 (d in the figure) or less.

It was confirmed from the results in FIG. 6 and FIG. 7 that, in the range of composition ratios described above, the crystal structure of the piezoelectric layer 6 obtained in the experimental example was a perovskite type structure, and in a monoclinic structure. Accordingly, it can be assumed that the polarization direction of the piezoelectric layer 6 was in an engineered domain arrangement in which the polarization direction is tilted with respect to the direction perpendicular to the film surface.

The piezoelectric constant (d₃₁) of the piezoelectric layer 6 obtained in the experimental example was about 175 pC/N in an absolute value. The piezoelectric constant (d₃₁) was measured in the following manner. First, the amount of displacement S1 of the elastic plate 55 of the piezoelectric element 100 in the actual liquid jet head 50 at the time of voltage application was measured using a laser Doppler meter. The value S1 was compared with the amount of displacement S2 obtained by simulation of piezoelectric displacement using a finite element method, whereby a finite difference between the actual piezoelectric constant (d₃₁) of the piezoelectric layer 6 and the piezoelectric constant (d′₃₁) of the piezoelectric layer 6 assumed by the finite element method. By this, the piezoelectric constant (d₃₁) of the piezoelectric layer 6 can be measured. It is noted that the physical values used in the simulation of piezoelectric displacement by a finite element method are Young's modulus of each layer, film stress, and assumed piezoelectric constant (d′₃₁) of the piezoelectric layer 6. In the present experimental example, S1 was 435 nm. Also, in the simulation, Young's modulus of the piezoelectric layer 6 was 65 GPa, and the in-plane compression stress was 110 MPa.

Also, in the experimental example, the leakage current of the piezoelectric layer 100 was less than 10⁻⁵ A/cm² when the applied voltage was 100 kV/m.

It was confirmed from the results of experiments that the piezoelectric element 100 in accordance with the present embodiment had favorable characteristics.

6. Next, a printer having the above-described liquid jet head is described. The case where a printer 600 in accordance with the present embodiment is an ink jet printer is described.

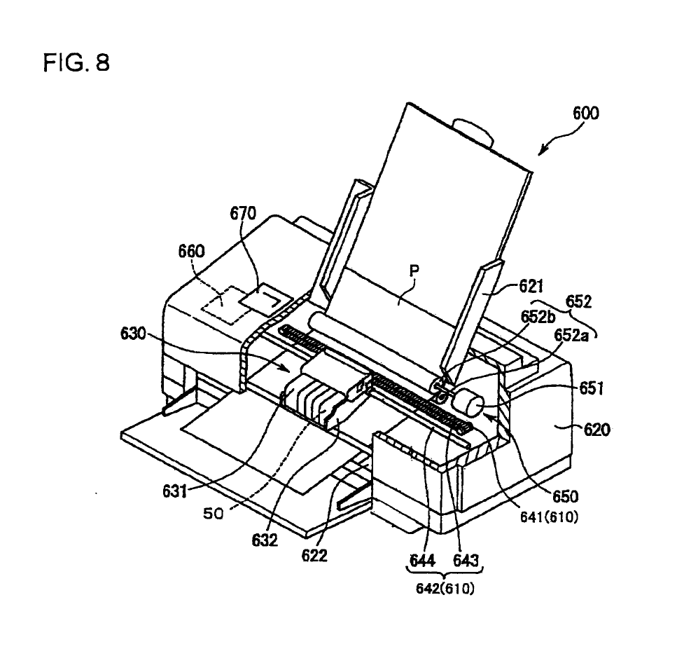

FIG. 8 is a schematic perspective view of the printer 600 in accordance with the embodiment of the invention. The printer 600 includes a head unit 630, a head unit driving section 610, and a controller section 660. Also, the printer 600 may include an apparatus main body 620, a paper feed section 650, a tray 621 for holding recording paper P, a discharge port 622 for discharging the recording paper P, and an operation panel 670 disposed on an upper surface of the apparatus main body 620.

The head unit 630 includes an ink jet type recording head (hereafter simply referred to as the “head”) 50 formed from the above-described liquid jet head. The head unit 630 is further quipped with ink cartridges 631 that supply inks to the head 50, and a transfer section (carriage) 632 on which the head 50 and the ink cartridges 631 are mounted.

The head unit driving section 610 is capable of reciprocally moving the head unit 630. The head unit driving section 610 includes a carriage motor 641 that is a driving source for the head unit 630, and a reciprocating mechanism 642 that receives rotations of the carriage motor 641 to reciprocate the head unit 630.

The reciprocating mechanism 642 includes a carriage guide shaft 644 with its both ends being supported by a frame (not shown), and a timing belt 643 that extends in parallel with the carriage guide shaft 644. The carriage 632 is supported by the carriage guide shaft 644, in a manner that the carriage 632 can be freely reciprocally moved. Further, the carriage 632 is affixed to a portion of the timing belt 643. By operations of the carriage motor 641, the timing belt 643 is moved, and the head unit 630 is reciprocally moved, guided by the carriage guide shaft 644. During these reciprocal movements, the ink is jetted from the head 50 and printed on the recording paper P.

The control section 660 can control the head unit 630, the head unit driving section 610 and the paper feeding section 650.

The paper feeding section 650 can feed the recording paper P from the tray 621 toward the head unit 630. The paper feeding section 650 includes a paper feeding motor 651 as its driving source and a paper feeding roller 652 that is rotated by operations of the paper feeding motor 651. The paper feeding roller 652 is equipped with a follower roller 652a and a driving roller 652b that are disposed up and down and opposite to each other with a feeding path of the recording paper P being interposed between them. The driving roller 652b is coupled to the paper feeding motor 651.

The head unit 630, the head unit driving section 610, the control section 660 and the paper feeding section 650 are provided inside the apparatus main body 620.

It is noted that the example in which the printer 600 is an ink jet printer is described above. However, the printer in accordance with the invention can also be used as an industrial droplet jet apparatus. As the liquid (liquid material) to be jetted in this case, a variety of liquids each containing a functional material whose viscosity is adjusted by a solvent or a disperse medium may be used.

7. Embodiments of the invention are described above in detail. However, those having ordinary skill in the art should readily understand that many modifications can be made without departing in substance from the new matters and effects of the invention. Accordingly, all of those modified examples are deemed included in the scope of the invention.

For example, the above-described piezoelectric elements in accordance with the embodiments of the invention are applicable to piezoelectric transducers that may be used for oscillators and frequency filters, angular velocity sensors that may be used for digital cameras, car navigation systems, and the like.

What is claimed is:

1. A piezoelectric element comprising:
a base substrate;
a lower electrode formed above the base substrate;
a piezoelectric layer that is formed above the lower electrode, and formed from a perovskite type oxide; and
an upper electrode formed above the piezoelectric layer,
wherein the piezoelectric layer is oriented to (100) crystal orientation in the pseudo-cubic crystal expression, and a crystal of the perovskite type oxide in a direction parallel to a lower surface of the piezoelectric layer has a lattice constant greater than a lattice constant of the crystal of the perovskite type oxide in a direction orthogonal to the lower surface of the piezoelectric layer.

2. A piezoelectric element according to claim 1, wherein the lattice constant of the crystal of the perovskite type oxide in a first direction among the directions parallel to the lower surface of the piezoelectric layer is equal to the lattice constant of the crystal of the perovskite type oxide in a second direction, among the directions parallel to the lower surface of the piezoelectric layer, orthogonal to the first direction in the pseudo-cubic crystal expression.

3. A piezoelectric element according to claim 1, wherein the crystal structure of the piezoelectric layer is a monoclinic structure.

4. A piezoelectric element according to claim 1, wherein the perovskite type oxide is expressed by a general formula ABO₃, where A includes lead (Pb), and B includes zirconium (Zr) and titanium (Ti).

5. A piezoelectric element according to claim 4, wherein B further includes lead (Pb).

6. A piezoelectric element according to claim 5, wherein the element B is expressed by (Pb_{X} Zr_{Y} Ti_{Z}), where X is 0.025 or more but 0.1 or less, and the sum of Y and Z is 1.

7. A piezoelectric element according to claim 5, wherein, when the amount of lead in the piezoelectric layer is t, and the amount of transition metal is u, t/u is 1.05 or more but 1.20 or less.

8. A piezoelectric element according to claim 1, wherein the perovskite type oxide is lead zirconate titanate.

9. A liquid jet head comprising the piezoelectric element recited in claim 1.

10. A printer comprising the piezoelectric element recited in claim 1.
